(19) United States
(12) Patent Application Publication
(10) Pub. No.: US 2006/0273364 A1
(43) Pub. Date: Dec. 7, 2006

(54) Identical/symmetrical metal shielding

(75) Inventors: R. Daniel McGrath, Pittsford, NY (US); R. Michael Guidash, Rochester, NY (US); Timothy J. Kenney, Pittsford, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/439,549

(22) Filed: May 24, 2006

Related U.S. Application Data
(60) Provisional application No. 60/686,105, filed on Jun. 1, 2005.

(51) Int. Cl. H01L 31/062

(52) U.S. Cl. 257/294

(57) ABSTRACT

An image sensor includes a unit cell having a plurality of pixels; the unit cell having a plurality of photodetectors having two or more subsets in which each subset has a physical shape which is different than the other subset; and light-shielding layers that create an aperture associated with each photodetector; wherein the light-shielding layers are positioned so that any physical translation of the light-shielding layers with respect to the photodetectors creates a substantially equal change in optical response of the photodetectors.

### CROSS-REFERENCE TO RELATED APPLICATIONS

Reference is made to and priority claimed from U.S. Provisional Application Ser. No. 60/686,105, filed Jun. 1, 2005, entitled IDENTICAL/SYMMETRICAL METAL SHIELDING.

### FIELD OF THE INVENTION

The invention relates generally to the field of image sensors and, more particularly, to such image sensors in which misalignment of the light shield does not change the size of the aperture.

### BACKGROUND OF THE INVENTION

Referring to FIG. 1, there is shown a prior art pixel 10 having a photodiode 20, circuitry 30, and isolation 40 and interconnect layers 50. interconnect layers are required to connect the photodiode 20 and the circuitry 30 and to connect the pixel 10 into the pixel array 70. The aperture (defined by layers 50a, 50b and the boundary of the photodiode 20 not covered by layer 50b) is set by the alignment of the photodiode 20 and the interconnect layers 50. Relative misalignment of the photodiode 20 to the interconnect layers 50 will cause the aperture to change size, which affects pixel performance.

Referring to FIG. 2, there is shown a prior art pixel supercell 80 made up of a plurality of pixels 10, such as first pixel 10a and second pixel 10b, where each pixel 10 contains a photodiode 20. The pixels 10 within the pixel supercell 80 share circuitry 30, and isolation 40 and interconnect layers 50. Given that the layout of the first pixel will differ from the layout of the second pixel due to the sharing of components, relative misalignment of the photodiode 20 to the interconnect layers 50 will cause the aperture (defined by layers 50a, 50b and the boundary of the photodiode 20 not covered by layers 50) to change size differently between the first pixel 10a and the second pixel 10b, which affects pixel performance. This will extend in a natural way to pixel supercells 80 containing more than two pixels 10.

Referring to FIG. 3, there is shown a prior art basic pixel 10 where variation in aperture 90 is eliminated by creating an aperture 90 on a third interconnect layer 50c. This layer 50c is the topmost of any other interconnect layers, such as a first interconnect layer 50a or a second interconnect layer 50b, because it must connect without gap in both directions. It also creates a minimum-sized aperture 90 since it must create a smaller aperture 90 than would result otherwise because it must be the controlling aperture.

Consequently, a need exist for matching optical response across manufacturing design tolerances.

### SUMMARY OF THE INVENTION

The present invention is directed to overcoming one or more of the problems set forth above. Briefly summarized, according to one aspect of the present invention, the invention resides in an image sensor comprising a unit cell having a plurality of pixels; the unit cell comprising (a) a plurality of photodetectors having two or more subsets in which each subset has a physical shape which is different than the other subset; (b) light-shielding layers that create an aperture associated with each photodetector; wherein the light-shielding layers are positioned so that any physical translation of the light-shielding layers with respect to the photodetectors creates a substantially equal change in optical response of the photodetectors.

These and other aspects, objects, features and advantages of the present invention will be more clearly understood and appreciated from a review of the following detailed description of the preferred embodiments and appended claims, and by reference to the accompanying drawings.

### ADVANTAGEOUS EFFECT OF THE INVENTION

The present invention has the following advantage of not changing the aperture size due to mis-alignment of the light shielding layers.

### BRIEF DESCRIPTION OF THE DRAWINGS

FIG. 1 is a top view of a prior art image sensor;

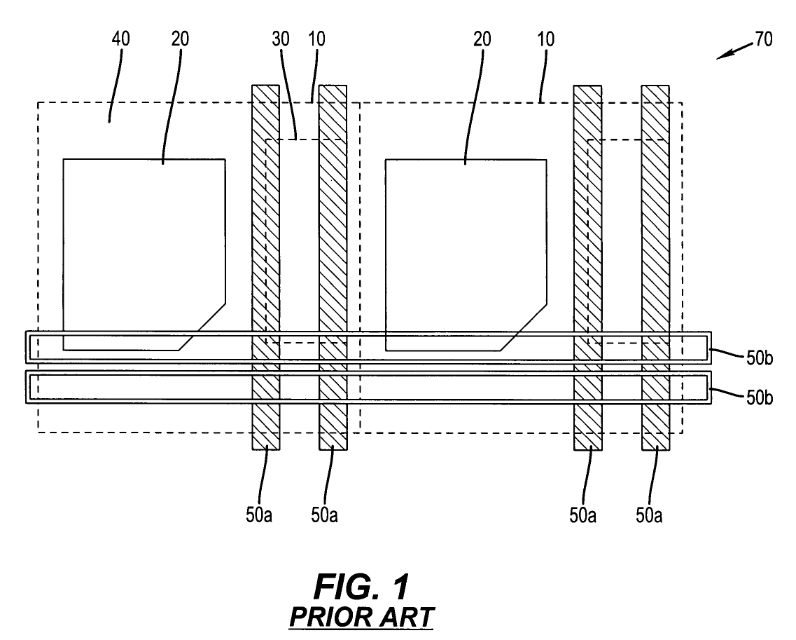

FIG. 2 is a top view of another prior art image sensor;

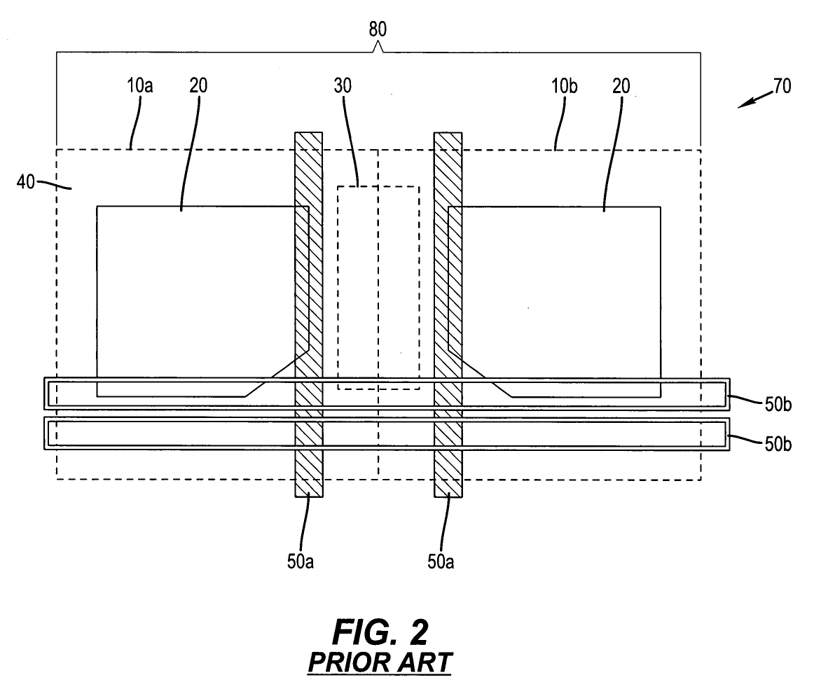

FIG. 3 is a top view of still another prior art image sensor;

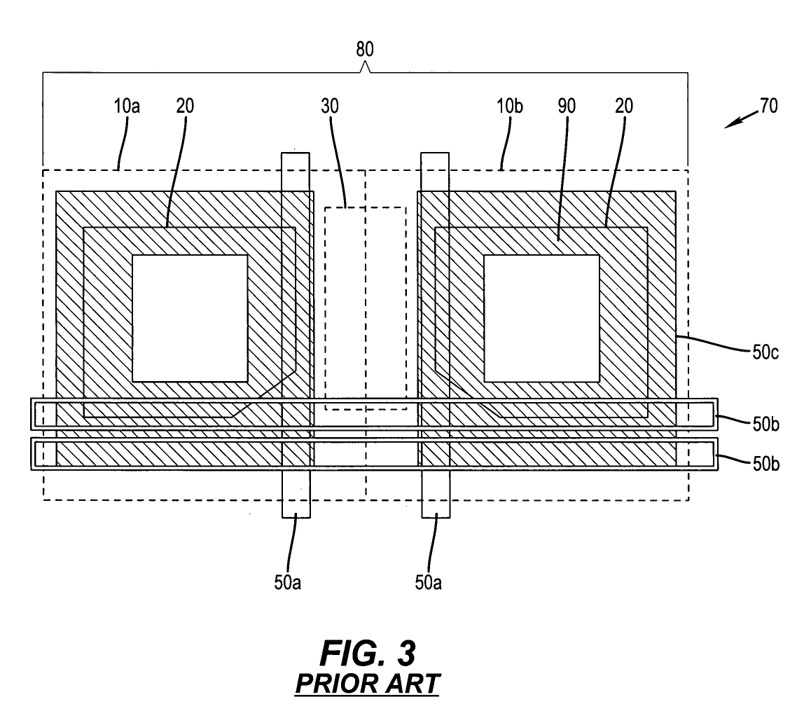

FIG. 4 is a top view of the image sensor of the present invention;

FIG. 5 is a top view of an alternative embodiment of the image sensor of the present invention;

FIG. 6 is a top view of a second alternative embodiment of the image sensor of the present invention;

FIG. 7 is a top view of a third alternative embodiment of the image sensor of the present invention;

FIG. 8 is a top view of a fourth alternative embodiment of the image sensor of the present invention;

FIG. 9 is a top view of a fifth alternative embodiment of the image sensor of the present invention; and

FIG. 10 is a digital camera for illustrating a typical commercial embodiment for the image sensor of the present invention.

### DETAILED DESCRIPTION OF THE INVENTION

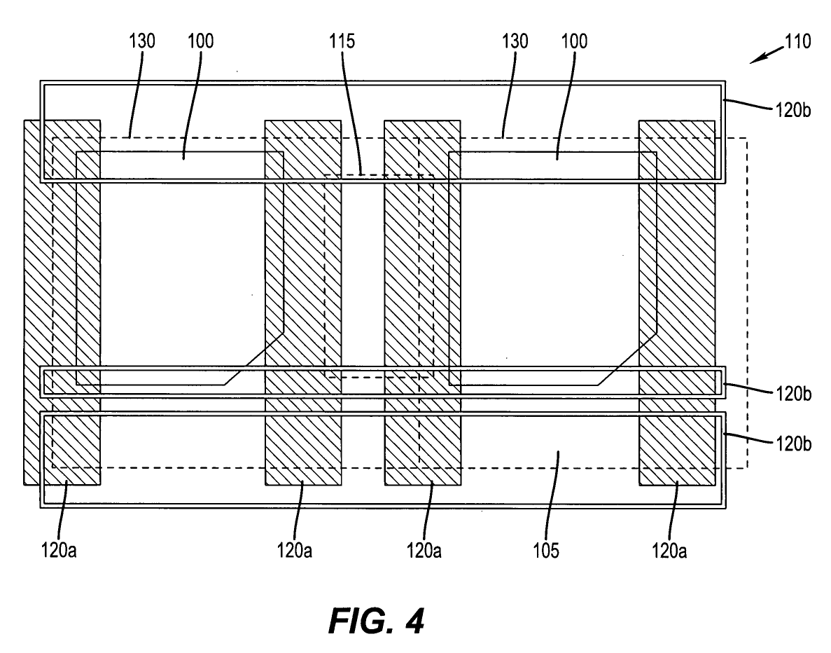

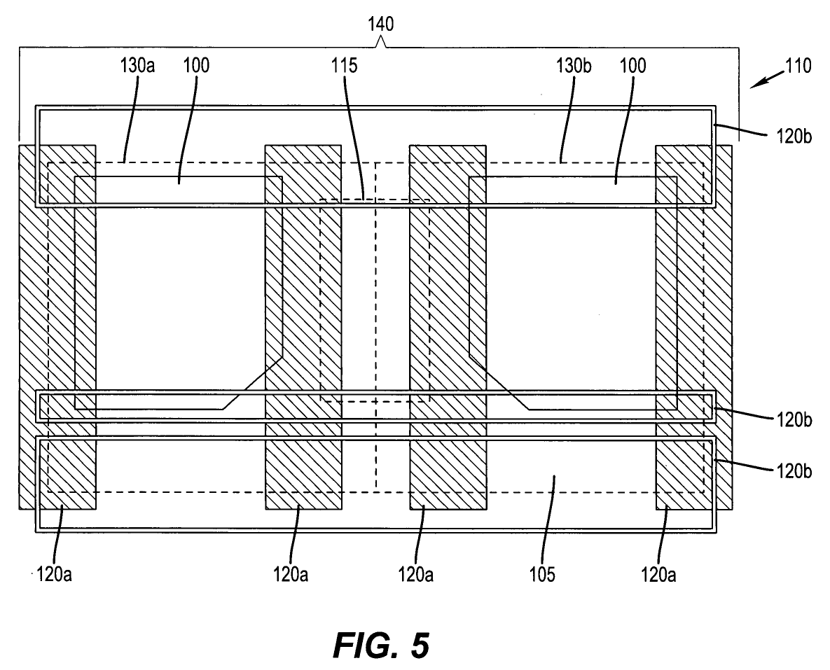

Referring to FIG. 4, there are shown two photodiodes 100 of the image sensor 110 of the present invention. Each photodiode 100 accumulates charge in response to light. The photodiodes 100 are shaped the same or substantially the same. There are a first interconnect layer 120a and second interconnect layer 120b that, in combination, form the light shield. It is instructive to note that preferably the first interconnect layer 120a and second interconnect layer 120b serve other purposes other than just a light shield. For example, they could serve as interconnections to provide biases or control clocks; to provide a means to read signals from the pixel 130; or to provide local interconnect within a pixel 130 or pixel supercell (defined as two or more pixels having non-identical shapes elements therein, but which having a repeating pattern across the image sensor 110), which pixel super cell is not shown in FIG. 4, but is shown in FIGS. 5, 7 and 9. The first interconnect layer 120a defines the aperture in one direction and the second interconnect layer 120b is positioned so that it defines the aperture in a direction orthogonal to the first interconnect layer. In this embodiment, the size of the aperture does not change with relative alignment of the first interconnect layer 120a and the second interconnect layer 120b to each other or to other layers, including any layers that define the photodiode 100. In other words, the light-shielding layers are positioned so that any physical translation of the light-shielding layers with respect to the photodiode 100 creates a substantially equal change in optical response of the photodiodes 100.

Still referring to FIG. 4, there is shown isolation 105 and circuitry 115. The isolation 105 keeps the photodiode 100 and circuitry 115 isolated from each other, and the circuitry 115 provides functions related to resetting and readout of the photodiode 100.

Referring to FIG. 5, there is shown an alternative embodiment of FIG. 4. In this embodiment, a supercell 140 consists of pixels 130a and 130b that include photodiodes 100. It is instructive to note that the photodiodes 100 are mirror images (or substantially mirror images) of each other. Although the photodiodes 100 are shown mirrored along the y-axis, the photodiodes 100 could be mirrored in either direction. The first interconnect layer 120a and second interconnect layer 120b are the same as in FIG. 4. In this embodiment, the size of the aperture (defined by layers 120a, 120b and the boundary of the photodiode 100 not covered by layers 120a and 120b) does not change with relative alignment of the first interconnect layer 120a and the second interconnect layer 120b to each other or to other layers, including any layers that define the photodiode 100.

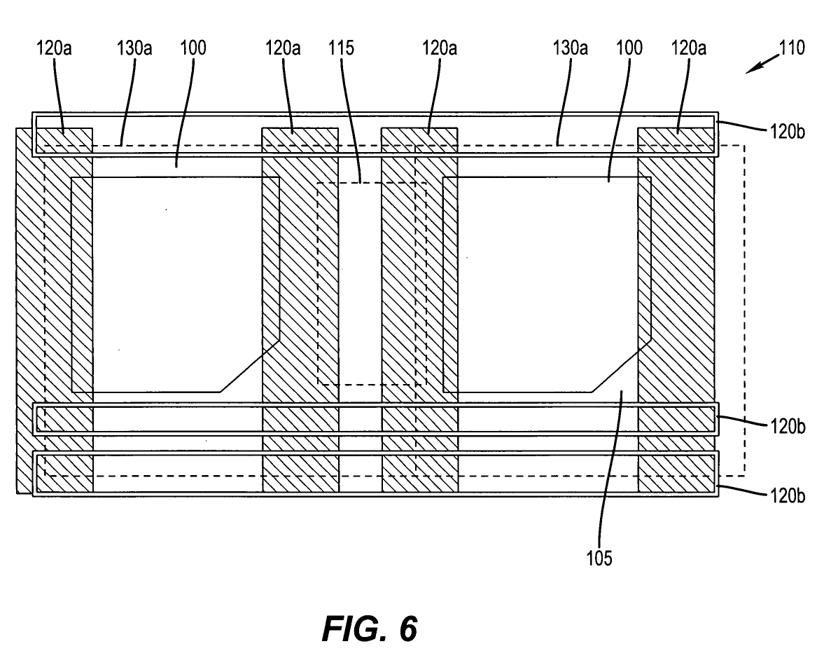

Referring to FIG. 6, there is shown a second alternative embodiment. The photodiodes 100 and first interconnect layer 120a and second interconnect layer 120b are the same as in FIG. 5 except that the second interconnect layer 120b has a shorter length in the y direction. It is instructive to note that the aperture is defined by first interconnect layer 120a and photodiode 100.

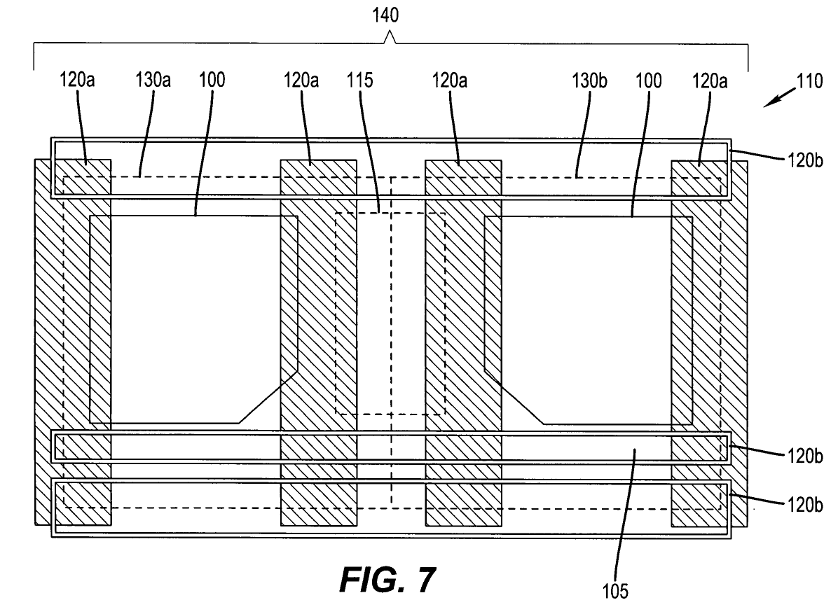

Referring to FIG. 7, there is shown a third alternative embodiment. This embodiment is the same as FIG. 6 except that the photodiodes 100 are mirror images (or substantially mirror images) of each other along the y-axis. Although the photodiodes 100 are shown mirrored along the y-axis, the photodiodes 100 could be mirrored in either direction. It is instructive to note that the aperture is defined as the same as in FIG. 6.

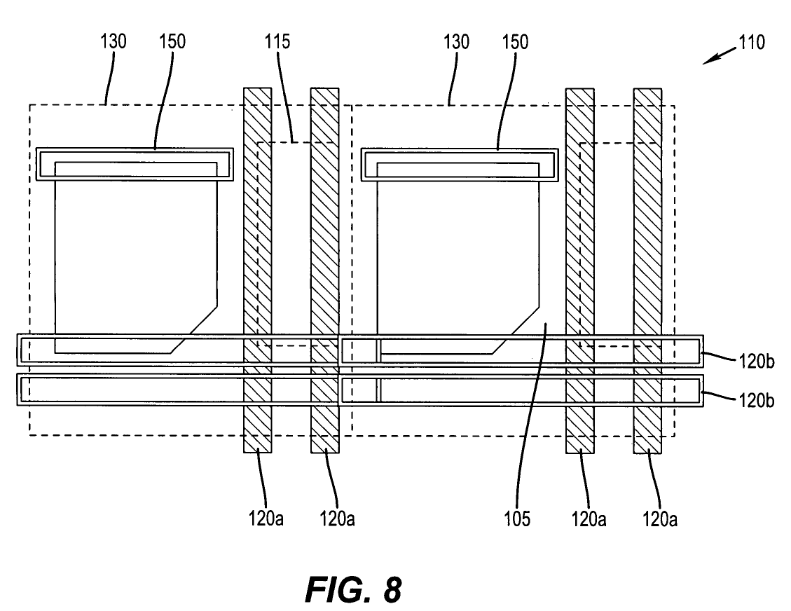

Referring to FIG. 8, there is shown a fourth alternative embodiment. In this embodiment, there are additional metal elements 150 that are physically on the second interconnect layer 120b. The additional metal elements 150 do provide any function except to form a portion of the aperture. Similarly as before, first interconnect layer 120a defines the aperture in one direction and the second interconnect layer 120b defines the aperture in an orthogonal direction. Similar to the other embodiments of the present invention, the size of the aperture does not change with relative alignment of the first interconnect layer 120a and the second interconnect layer 120b to each other or to other layers, including any layers that define the photodiode 100.

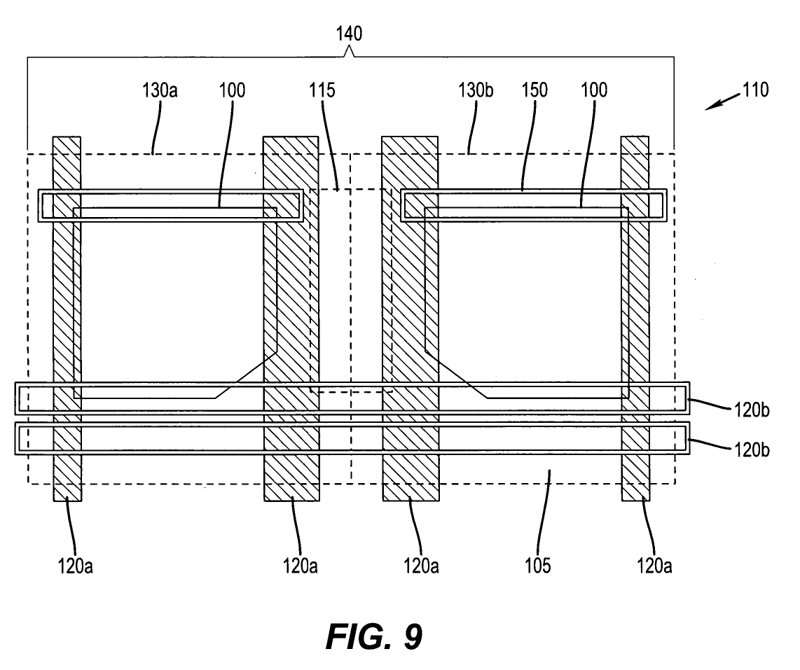

Referring to FIG. 9, there is shown a fifth alternative embodiment which is the same as FIG. 8 except that the photodiodes 100 are mirror images (or substantially mirror images) of each other along the y-axis.

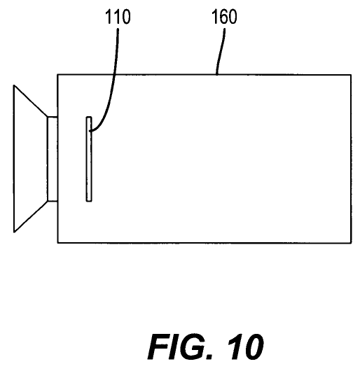

Referring to FIG. 10, there is shown a digital camera 160 having the image sensor 110 of the present invention therein for illustrating a typical commercial embodiment.

Finally, for clarity, it is noted that the word “subset” as used herein includes one or more photodetectors.

The invention has been described with reference to a preferred embodiment. However, it will be appreciated that variations and modifications can be effected by a person of ordinary skill in the art without departing from the scope of the invention.

### Parts List

10 prior art pixel
10a first pixel
10b second pixel
20 photodiode
30 circuitry
40 isolation layer
50 interconnect layer
50a interconnect layer
50b interconnect layer
50c interconnect layer
70 pixel array
80 prior art pixel supercell
90 aperture
100 photodiode
105 isolation
110 image sensor
115 circuitry
120a first interconnect layer
120b second interconnect layer
130 pixel
130a pixel
130b pixel
140 pixel supercell
150 additional metal element
160 digital camera

1. An image sensor comprising:
a unit cell having a plurality of pixels; the unit cell comprising:
(a) a plurality of photodetectors having two or more subsets in which each subset has a physical shape which is different than the other subset; and
(b) light-shielding layers that create an aperture associated with each photodetector; wherein the light-shielding layers are positioned so that any physical translation of the light-shielding layers with respect to the photodetectors creates a substantially equal change in optical response of the photodetectors.

2. The image sensor as in claim 1, wherein each subset has the physical shape which is a mirror image of the other subset.

3. The image sensor as in claim 1, wherein the light-shielding layers are composed of either polysilicon or interconnect metal.

4. The image sensor as in claim 1, wherein a specific physical region of one or more of the light-shielding layers are placed solely to create the aperture in conjunction with the other light-shielding layers.

5. The image sensor as in claim 1, wherein one or more of the light-shielding layers are placed solely to create the aperture.

6. The image sensor as in claim 1, wherein the subsets each include an equal number of photodetectors.

7. An image sensor comprising:
a unit cell having a plurality of pixels; the unit cell comprising:
(a) two or more subsets of pixels in which each subset has a photodetector and an interconnect pattern which is different than the other subset; and
(b) light-shielding layers that create an aperture associated with each photodetector; wherein the light-shielding layers are positioned so that any physical translation of the light-shielding layers with respect to the photodetectors creates a substantially equal change in optical response of the photodetectors.

8. The image sensor as in claim 7, wherein each subset has the physical shape which is a mirror image of the other subset.

9. The image sensor as in claim 7, wherein the light-shielding layers are composed of either polysilicon or interconnect metal.

10. The image sensor as in claim 7, wherein a specific physical region of one or more of the light-shielding layers are placed solely to create the aperture in conjunction with the other light-shielding layers.

11. The image sensor as in claim 7, wherein the light-shielding layers are placed solely to create the aperture.

12. The image sensor as in claim 7, wherein the subsets each include an equal number of photodetectors.

13. A camera comprising:
an image sensor comprising:
a unit cell having a plurality of pixels; the unit cell comprising:
(a) a plurality of photodetectors having two or more subsets in which each subset has a physical shape which is different than the other subset; and
(b) light-shielding layers that create an aperture associated with each photodetector; wherein the light-shielding layers are positioned so that any physical translation of the light-shielding layers with respect to the photodetectors creates a substantially equal change in optical response of the photodetectors.

14. The camera as in claim 13, wherein each subset has the physical shape which a mirror image of the other subset.

15. The camera as in claim 13, wherein the light-shielding layers are composed of either polysilicon or interconnect metal.

16. The camera as in claim 13, wherein a specific physical region of one or more of the light-shielding layers are placed solely to create the aperture in conjunction with the other light-shielding layers.

17. The camera as in claim 13, wherein one or more of the light-shielding layers are placed solely to create the aperture.

18. The camera as in claim 13, wherein the subsets each include an equal number of photodetectors.

19. A camera comprising:
an image sensor comprising:
a unit cell having a plurality of pixels; the unit cell comprising:
(a) two or more subsets of pixels in which each subset has a photodetector and an interconnect pattern which is different than the other subset; and
(b) light-shielding layers that create an aperture associated with each photodetector; wherein the light-shielding layers are positioned so that any physical translation of the light-shielding layers with respect to the photodetectors creates a substantially equal change in optical response of the photodetectors.

20. The camera as in claim 19, wherein each subset has the physical shape which is a mirror image of the other subset.

21. The camera as in claim 19, wherein the light-shielding layers are composed of either polysilicon or interconnect metal.

22. The camera as in claim 19, wherein a specific physical region of one or more of the light-shielding layers are placed solely to create the aperture in conjunction with the other light-shielding layers.

23. The camera as in claim 19, wherein the light-shielding layers are placed solely to create the aperture.

24. The camera as in claim 20, wherein the subsets each include an equal number of photodetectors.
